(19) United States
(12) Patent Application Publication
(10) Pub. No.: US 2014/0347829 A1
(43) Pub. Date: Nov. 27, 2014

(54) ELECTRONIC APAPRATUS

(71) Applicant: Kabushiki Kaisha Toshiba, Tokyo (JP)

(72) Inventor: Akira Tanaka, Hamura (JP)

(73) Assignee: KABUSHIKI KAISHA TOSHIBA, Tokyo (JP)

(21) Appl. No.: 14/065,230

(22) Filed: Oct. 28, 2013

(30) Foreign Application Priority Data
May 21, 2013 (JP) 2013-107328

(51) Int. Cl. H05K 7/06

(52) U.S. Cl. CPC H05K 7/06
USPC 361/752; 361/679.01

(57) ABSTRACT

According to one embodiment, an electronic apparatus includes a housing and electronic components provided in the housing. The housing has a gap as an intrusion path through which liquid or a foreign matter may enter the housing such as a periphery of a connector to which external equipment is connected. The liquid sometimes enters the housing from an outside of the housing through the gap. The liquid entering the housing from the outside through the gap is collected by an adsorption power based on a capillary phenomenon of a collecting portion.

### CROSS-REFERENCE TO RELATED APPLICATIONS

This application is based upon and claims the benefit of priority from Japanese Patent Application No. 2013-107328, filed May 21, 2013, the entire contents of which are incorporated herein by reference.

### FIELD

Embodiments described herein relate generally to an electronic apparatus comprising a number of electronic components.

### BACKGROUND

An electronic apparatus such as a portable computer (PC) is placed in various use environments such as an office and a home. The apparatus sometimes breaks down, e.g., when a drink or water in a vase is spilled, or when urine of a pet is splashed.

In the use environments, an accident caused by carelessness of a user is hard to prevent. If liquid enters the electronic apparatus, wiring of a circuit board or terminals of electronic components may be short-circuited, and fire may be caught in the worst case.

Also, when time passes after the liquid enters the electronic apparatus, the liquid erodes the wiring of the board or the terminals of the components and is transformed, and a kind of the liquid entering the electronic apparatus is hard to specify. In addition, when time passes and the liquid is dried, an intrusion path of the liquid is hard to find. In such a case, a cause of the breakdown is also hard to examine.

Accordingly, it is to be hoped that the electronic apparatus will be developed to prevent a serious failure such as ignition even if the liquid enters the housing and to easily specify the liquid entering the housing as well as the intrusion path of the liquid.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a schematic view of a printed circuit board incorporated into an electronic apparatus of an embodiment.

FIG. 2 is an enlarged view of a region R2 in FIG. 1.

FIG. 3 is an enlarged view of a region R3 in FIG. 1.

FIG. 4 is a schematic view of an electronic apparatus of a first embodiment.

FIG. 5 is a schematic view of a back surface of a main body of the electronic apparatus of FIG. 4.

FIG. 6 is an enlarged view of part of the electronic apparatus, in which part of a housing of the electronic apparatus is detached in a region R6 of FIG. 4.

FIG. 7 is an enlarged view of a rear surface of the part detached in FIG. 6 in a region R7 of FIG. 4.

FIG. 8 is an enlarged view of part of the electronic apparatus, in which an insulator is attached to the printed circuit board of FIG. 6.

FIG. 9 is an enlarged view of part of a surface side of the main body of the electronic apparatus of a second embodiment.

FIG. 10 is a perspective view of part of the electronic apparatus, in which the part of the surface side of the main body of the electronic apparatus of FIG. 9 is detached.

FIG. 11 is a perspective view of a back surface of the electronic apparatus of a third embodiment, which is seen from an oblique upper right direction.

FIG. 12 shows a first example of collection patterns of FIGS. 7 and 10.

FIG. 13 shows a second example of the collection patterns of FIGS. 7 and 10.

FIG. 14 shows a third example of the collection patterns of FIGS. 7 and 10.

FIG. 15 shows a fourth example of the collection patterns of FIGS. 7 and 10.

FIG. 16 shows a fifth example of the collection patterns of FIGS. 7 and 10.

FIG. 17 shows a sixth example of the collection patterns of FIGS. 7 and 10.

FIG. 18 shows a porous member attached instead of the collection patterns of FIGS. 7 and 10.

### DETAILED DESCRIPTION

In general, according to one embodiment, an electronic apparatus comprises a housing and electronic components provided in the housing. The housing comprises a gap (an intrusion path) through which liquid (or a foreign matter) may enter the housing such as a periphery of a connector to which external equipment is connected. The liquid sometimes enters the housing from an outside of the housing through the gap. The liquid entering the housing from the outside through the gap is collected by an adsorption power based on a capillary phenomenon of a collecting portion.

Various embodiments will be described in detail hereinafter with reference to the accompanying drawings.

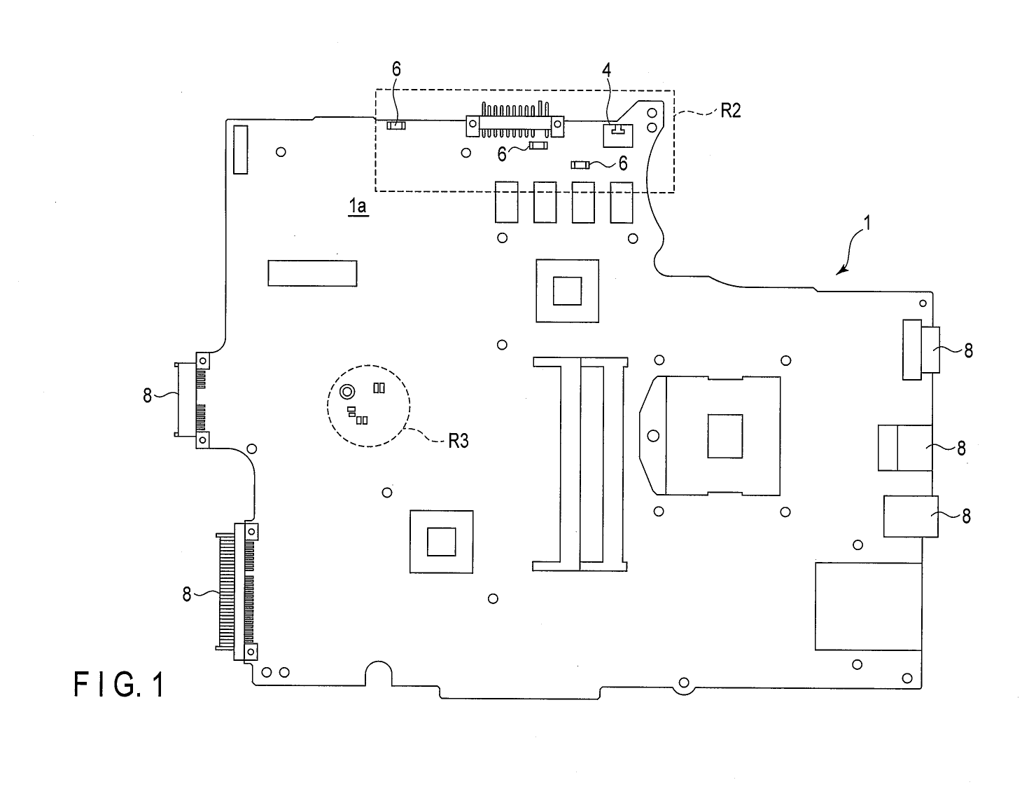

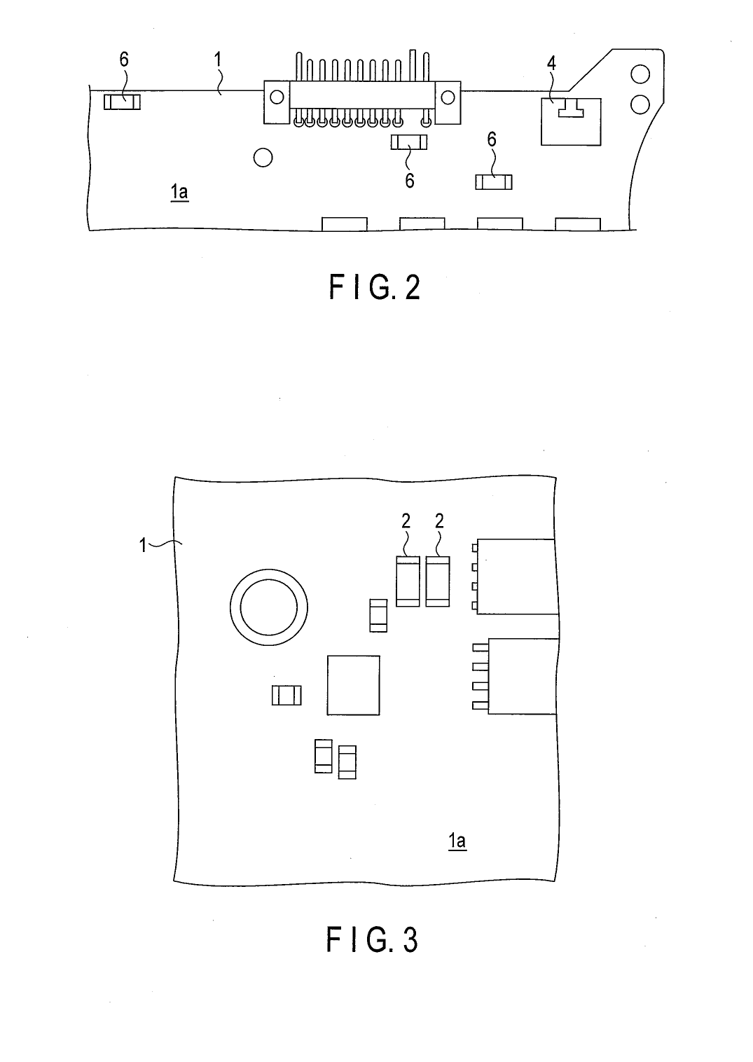

First, an example of a printed circuit board 1 (hereinafter referred to as a board 1) built into the electronic apparatus according to an embodiment is explained with reference to FIGS. 1 to 3. FIG. 1 is an overall view of the board 1, FIG. 2 is a partially enlarged view of a region R2 of FIG. 1, and FIG. 3 is a partially enlarged view of a region R3 of FIG. 1.

The board 1 comprises a surface 1a on which a number of electronic components are mounted, and a wiring pattern is formed on the surface 1a. The board 1 is positioned and secured in the housing of the electronic apparatus to be described.

In this embodiment, e.g., a plurality of condensers 2 (partially shown), a power source jack 4 and three fuses 6 are mounted on the surface 1a of the board 1 as the electronic components. In addition, a plurality of connectors 8 for connecting the external equipment such as a USB connector are attached to the surface 1a near a periphery of the board 1. An insertion port of the connectors 8 is exposed to the outside of the housing through an opening of the housing with the board 1 attached to an inside of the housing. Moreover, various electronic components as shown or not shown are mounted on the surface 1a of the board 1.

The condensers 2 and the power source jack 4 in these electronic components are electronic components belong to electronic components which should not be short-circuited because these are may emit smoke or cause a burnout when being short-circuited. As another structure which should not be short-circuited, a structure to which a high voltage is applied is conceivable such as a power supply circuit on the surface 1a of the board 1 and a battery in an apparatus body 12. Ignition due to the burnout will be caused by inflammation of dust accumulated in the apparatus body 12.

On the other hand, since the fuses 6 can prevent an excessive current from flowing through a whole circuit by having it actively broken, when liquid enters the housing as described below, the fuse 6 belongs to electronic components to be actively broken.

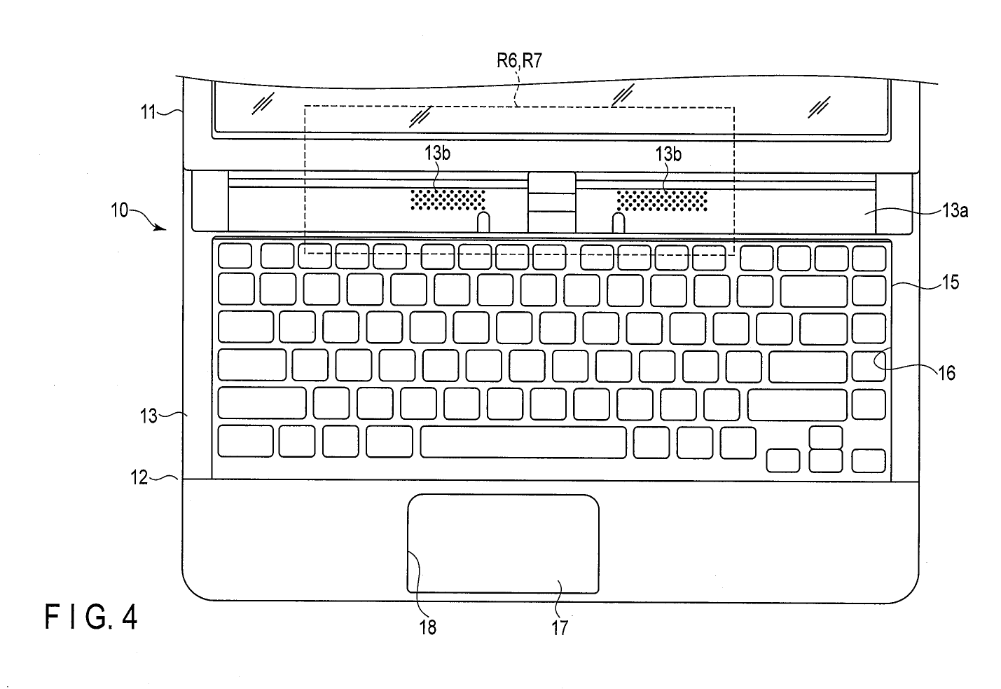

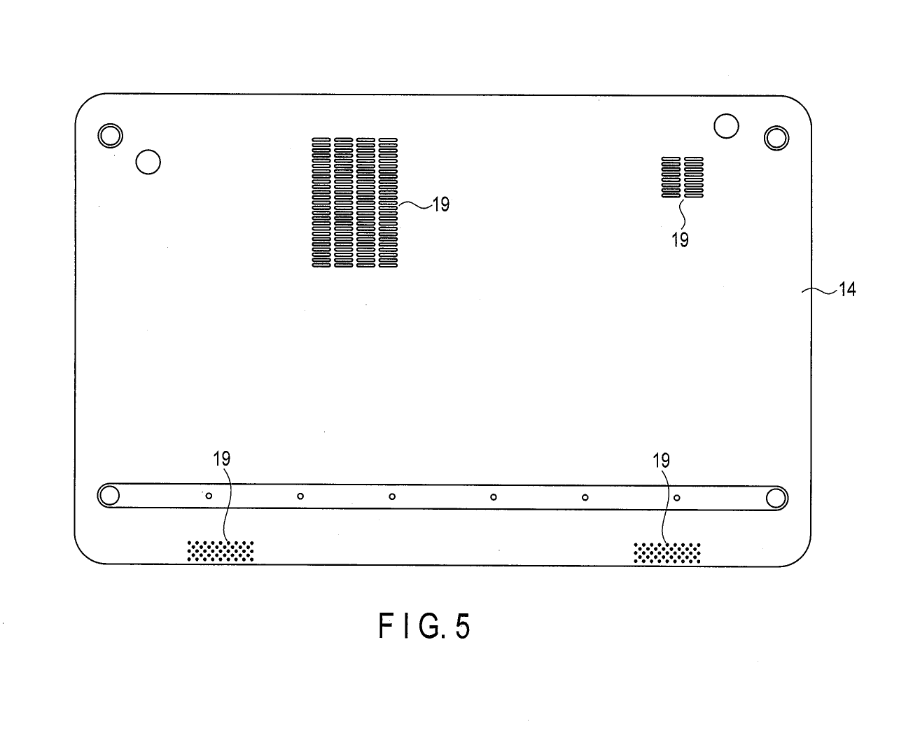

FIG. 4 is a schematic view of a notebook typed portable computer (notebook PC) 10 as the electronic apparatus according to the first embodiment. Part of a display housing 11 of the notebook PC 10 is ruptured and omitted, and an outline structure of a surface side of the apparatus body 12 is shown. Also, FIG. 5 is a schematic view of a structure of a back surface side of the apparatus body 12 of the notebook PC 10.

The apparatus body 12 of the notebook PC 10 comprises housings 13 and 14 of an obverse side and a reverse side in which the board 1 as described above is stored and attached. The display housing 11 is overlaid on the obverse side housing 13 at a closed position. The structure of the board 1 itself or a layout of the electronic components is not necessarily identical to that of FIG. 1. In this embodiment, the board on which electronic components such as the condensers 2, the power source jack 4, the fuses 6 and the connectors 8 are mounted are referred to as “board 1” and explained.

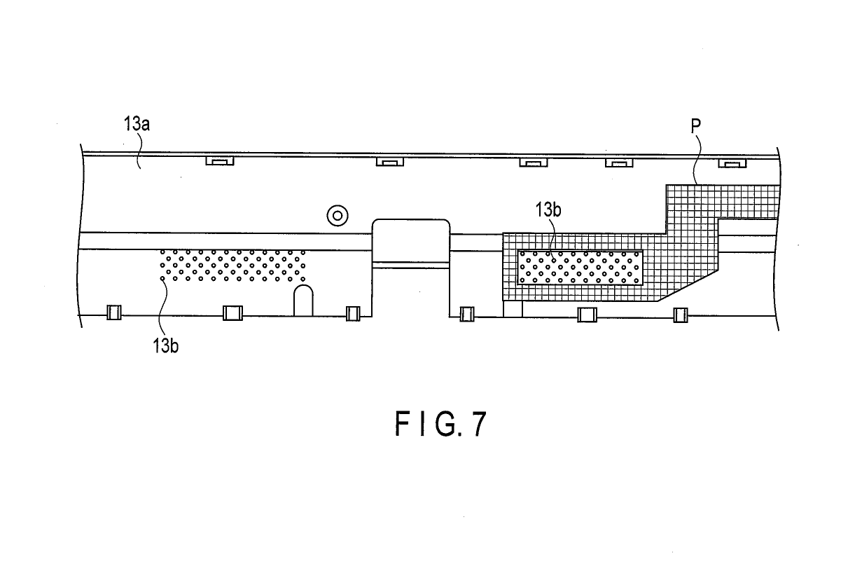

As shown in FIG. 4, a comparatively-large rectangular opening 16 for exposing a keyboard 15 and a comparatively-small rectangular opening 18 for arranging a mouse pad 17 are provided in the obverse side housing 13. Also, in FIG. 4, a housing portion 13a above the keyboard 15 comprises a structure detachable from the housing 13. The structure of a rear surface of part 13a of the housing 13 is shown in FIG. 7. A hole group 13b (an intrusion path) comprising a plurality of holes for a speaker and penetrating the housing portion 13a.

Also, as shown in FIG. 5, an air hole 19 (an intrusion path) comprising a hole group in which a number of small holes for intake and exhaust are gathered and penetrating the back side housing 14 is provided in a plurality of portions of the housing 14. In addition, a plurality of openings (intrusion paths) configured to expose the above-described insertion port of the connectors 8 are provided at the side surfaces of the housings 13 and 14, i.e., in right and left portions of FIG. 5.

Then, if, e.g., water (liquid) in a glass is spilled on the obverse side housing 13, the water may enter the housing through a gap (an intrusion path) of the opening 16 in which the keyboard 15 is arranged, a gap (an intrusion path) of the opening 18 in which the mouse pad 17 is arranged, a gap (an intrusion path) surrounding the housing portion 13a, the hole group 13b for the speaker, an opening for the connectors 8, etc. In this case, if the water directly dropped from an internal surface of the housing 13 through the obverse 1a and/or the rear surface of the board 1 or through the internal surface of the housing 13 splashes on the condensers 2, the power source jack 4 or the power supply circuit belonging to the above-described electronic components which should not be short-circuited, it may be short-circuited and the burnout may occur.

In this embodiment, to prevent such a failure, collection patterns P functioning as the collecting portions are provided at an appropriate location of the internal surfaces, which are the surfaces facing an inside of the apparatus body 12, of the housings 13 and 14. An example of the collection patterns P of this “external foreign matter collecting housing” is hereinafter explained.

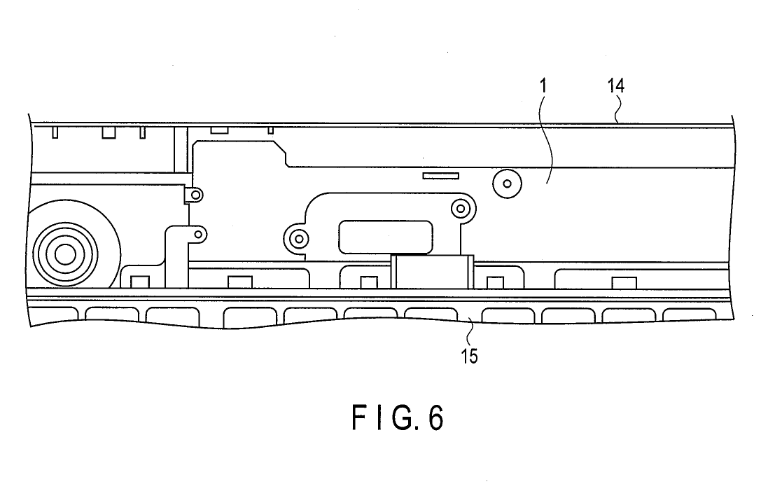

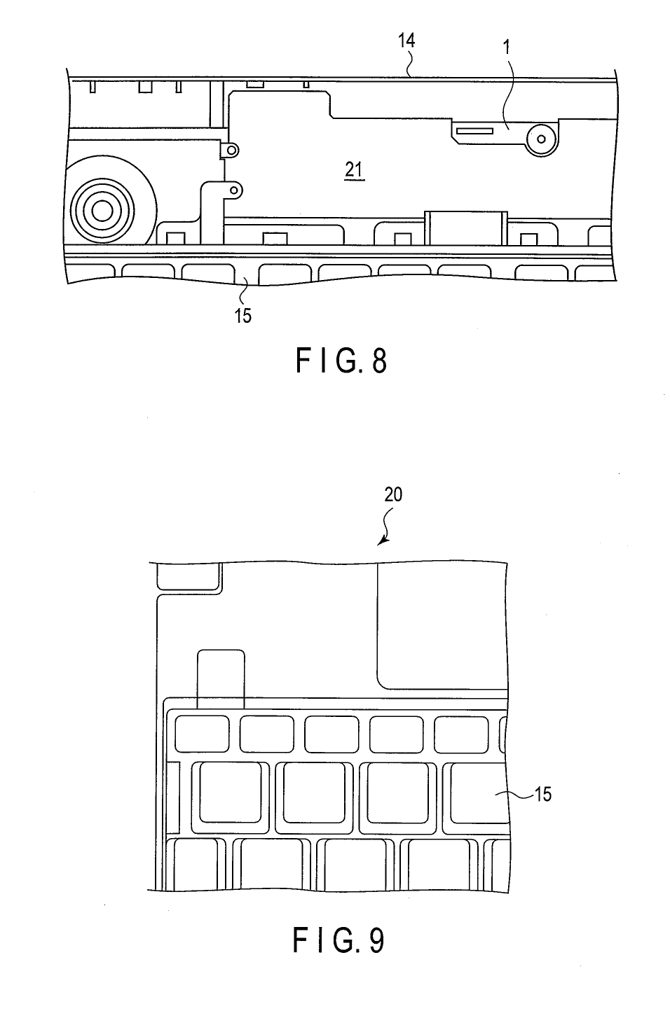

FIG. 6 is an enlarged view of the apparatus body 12 of a region R6 in FIG. 4 with the housing portion 13a of the obverse side detached. FIG. 7 is an enlarged view of the internal surface (the rear surface) of the housing portion 13a in a region R7 of FIG. 4. FIG. 8 indicates a state where part of the board 1 arranged in the apparatus body 12 of FIG. 6 is covered with an insulator 21. The case where water enters the housing through the hole group 13b for the speaker provided in housing portion 13a is assumed.

The collection patterns P connected to the hole group 13b are provided at the internal surface (the rear surface) of the housing portion 13a. The collection patterns P are arranged to surround a periphery of the hole group 13b for the speaker, and extends outward in a direction away from an edge of the board 1. Each of the collection patterns P is positioned not to arrange the electronic components which should not be short-circuited such as the condensers 2 and the power source jack 4 in a location overlaid on the patterns and/or a location adjacent to the patterns and to lead water to avoid the electronic components.

In the collection patterns P of this embodiment, lattice-shaped minute groove channels are formed on the internal surface of the housing portion 13a. The collection patterns P are formed simultaneously with molding of the housing portion 13a. That is, a die for forming such minute grooves is used. The collection patterns P preferably comprise a location and a size which do not reduce machine strength of the housing by providing the grooves.

More specifically, in each groove of the collection patterns P, a plurality of hairlines comprising a width of approximately 100 μm and a depth of approximately 50 μm are crossed. Each groove of the collection patterns P comprises a function of absorbing liquid such as water by the capillary phenomenon. The collection patterns P may comprise any structure such as depressions, holes, dots, embosses and minute projections comprising various forms, if the patterns comprise the structure in which capillary force can be applied to the liquid, as well as a structure in which straight grooves are formed at the internal surface of the housing as in this embodiment. An example of the collection patterns P is described later.

Then, water entering the housing through the hole group 13b of the housing portion 13a is absorbed by the capillary phenomenon of the collection patterns P of the internal surface of the housing portion 13a located immediately close to the hole group 13b. The intrusion path is oriented in a desired direction (in a direction away from the board 1 in this embodiment) and the absorbed water is trapped in the grooves of the collection patterns P. In this embodiment, according to this, at least the electronic components which should not be short-circuited may be prevented from being covered with water, and water unexpectedly entering the housing maybe controlled in a desired path direction.

Also, water absorbed in the grooves of the collection patterns P is directly trapped in the grooves through the hole group 13b of the housing portion 13a. Accordingly, since the water is not liquid which wetted the board 1 and eroded the wiring pattern and terminals, what the trapped liquid is can be easily discriminated by subsequent componential analysis. In the case of this embodiment, it can be discriminated that the liquid collected from the grooves is water.

Moreover, regarding the liquid trapped in the grooves of the collection patterns P, since only a small quantity of impurities remain as a residue and traces are left in the groove even if the outside of the housing portion 13a is wiped, the intrusion path of the liquid can be easily specified. At this moment, to make the intrusion path of the liquid easier to find, it may be possible to perform special surface treatment on the grooves of the collection patterns P, to use a material whose color changes once it gets wet with the liquid, and to adopt a structure (e.g., metal deposition) for facilitating various chemical analyses (FT-IR, SEM/EDX and EPMA).

As shown in FIG. 8, the insulator 21 is attached to a location above the obverse 1a of the board 1 overlaid on the collection patterns P. Even if a comparatively-large quantity of liquid enters the housing through the hole group 13b, the liquid does not directly dripped on the surface 1a of the board 1. However, the liquid may reach the surface 1a of the board 1 through an outer surface of the insulator 21. Also, the liquid may directly reach the board from the housing regardless of the presence of the insulator 21. By assuming such a case, the collection patterns P can be provided at the surface 1a of the board 1.

In this case, the collection patterns P provided in the board 1 are preferably arranged to avoid the electronic components which should not be short-circuited such as the condensers 2 and the power source jack 4. Alternatively, the collection patterns P can be laid out to lead the liquid to the electronic components to be actively blown such as the fuses 6. In the latter case, since the fuses 6 may be first blown to cut off power supplying when the liquid enters the housing, a failure caused by an excessive current flowing to the wiring pattern of the board 1 may be prevented. In this case, even if the condensers 2 and the power source jack 4 are covered with the liquid after the fuses 6 are blown, these electronic components are not short-circuited.

It should be noted that although the case where the liquid enters the housing through the hole group 13b of the housing portion 13a is assumed above, this embodiment is not limited to this case. The liquid may enter the apparatus body 12 through other intrusion paths such as the gap of the opening 16 of a periphery of the keyboard 15, the gap of the opening 18 of a periphery of the mouse pad 17, the gap surrounding the housing portion 13a, the air hole 19 of the back surface side housing 14 and the gap of the opening of the connectors 8. Thus, the collection patterns P as described above can be formed on the internal surface of the housing or the obverse or the reverse of the board 1 depending on each intrusion path. Thus, it can be easily specified from what portion of the housing the liquid enters the housing by forming the collection patterns P depending on each intrusion path.

To verify an advantage obtained by the above-described collection patterns P, a liquid immersion test was carried out on a conventional notebook PC without the collection patterns P and a notebook PC with the collection patterns P of this embodiment. A result of the test is considered below. It should be noted that citric acid which is one of organic acids easy to erode a circuit when it enters the notebook PC was used in this test.

First, an aqueous solution of citric acid prepared in a 500 ml PET bottle was sprinkled from obliquely above an apparatus body of the conventional notebook PC without the collection patterns P. Consequently, it could be confirmed by visual observation that part of the aqueous solution of citric acid entered the housing from a periphery of an SD media slot and an ODD.

When the PC was disassembled and an inside of the notebook PC was investigated a week later, it could be confirmed that a white corrosive was generated in a solder joint portion on the surface 1a of the board 1 and part of a lead of the electronic components. When the white corrosive was subjected to a Fourier transform infrared spectrometer (FT-IR), organic acid salt was detected. Also, when the white corrosive was analyzed by a scanning electron microscope (SEM)/an energy dispersive X-ray microanalyzer (EDX), C, O and Sn were detected, and data supporting the result of the FT-IR was obtained. By this result, it could be confirmed that organic acid was mixed in the notebook PC.

However, a result of analysis was merely obtained as a reactant with a solder component in the analysis of such a corrosive, and it was difficult to determine that the liquid used for the test was citric acid.

The same test was carried out for the notebook PC with the collection patterns P of this embodiment. When the notebook PC was disassembled and the inside was investigate a week later, no notable corrosive was confirmed in the solder joint portion on the surface 1a of the board 1 or the lead of the electronic components.

Also, when the grooves of the collection patterns P were observed by an optical microscope, a residue extracted by drying the liquid trapped in the grooves was confirmed in the collection patterns P formed inside the housing around the SD media slot. At this moment, an appearance, i.e., a visual aspect such as a color and a shape, of the collection patterns P changed in comparison with the appearance before inspection. That is, the presence of the residue could be confirmed to some extent even by visual observation.

Since the collection patterns P are formed in an inner surface of the housing, the visual aspect of the collection patterns P does not change unless the liquid enters the housing and flows through the grooves. In other words, by the change of the visual aspect of the collection patterns P, e.g., by lost of a luster, it may be determined that the liquid enters the housing through the collection patterns P. When the residue attached to the grooves of the collection patterns P was collected and analyzed by the FT-IR for confirmation, it accorded with an IR spectrum of citric acid.

From the above result, it was understood not only that the collection patterns P of this embodiment could prevent the liquid from being led to the electronic components or wiring on the board 1, but that the intrusion path of the liquid and the liquid component could be easily specified.

Also, if this collecting portion is explained to a user, a determination result of a cause of the liquid entering the housing is easily accepted by a user, and repair may be dealt with more smoothly.

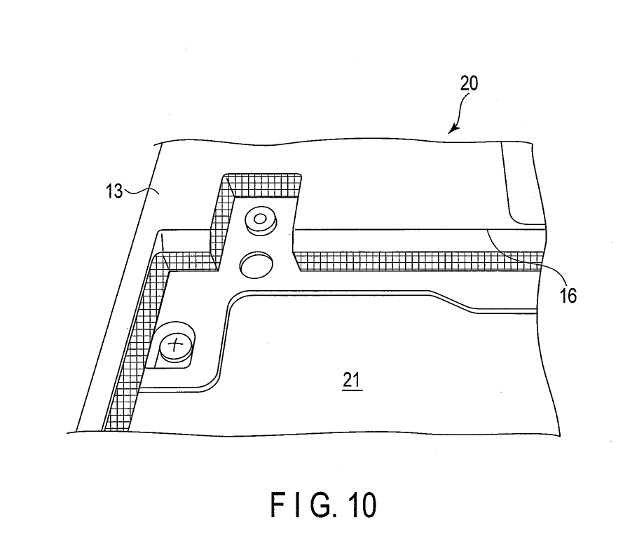

Next, a second embodiment is explained with reference to FIGS. 9 and 10. FIG. 9 is an enlarged view of part of a notebook PC 20 which is an example of the electronic apparatus of the second embodiment. FIG. 10 is a perspective view of part of the electronic apparatus, in which the obverse side housing 13 of the apparatus body 12 of this notebook PC 20 is detached. In the following explanation, structural elements identical to those in the first embodiment will be denoted by the same reference numerals as in the first embodiment, and their detailed explanations will be omitted.

The notebook PC 20 of this embodiment comprises the collection patterns P at an edge of the opening 16 of the housing 13 for attaching the keyboard 15. As shown in FIG. 10, the insulator 21 is arranged on the surface 1a of the board 1 when the keyboard 15 is detached. The liquid may be led to the board 1 through the edge of the insulator 21 when the liquid enters the housing from a gap (an intrusion path) of a periphery of the opening 16. Thus, the notebook PC 20 of this embodiment comprises the collection patterns P at the edge of the opening 16.

Since the collection patterns P function in the same manner as the collection patterns P of the first embodiment, the liquid entering the housing through the gap of the opening 16 is trapped in minute channels of the collection patterns P by the capillary phenomenon.

As shown above, an advantage similar to that of the first embodiment may be obtained by the notebook PC 20 also in this embodiment. That is, the notebook PC 20 may collect the liquid entered the housing, and may also specify the intrusion path and component of the liquid.

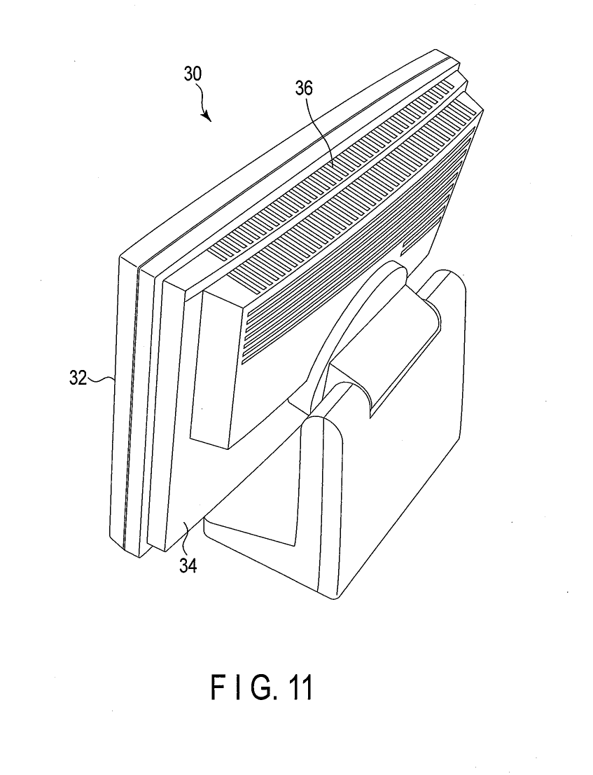

FIG. 11 is a perspective view of a desktop-typed computer 30 (hereinafter referred to as a desktop PC 30) which is an electronic apparatus of a third embodiment and seen from a rear side.

The desktop PC 30 comprises air holes 36 (intrusion paths) in which a plurality of slit holes formed to penetrate a housing 34 are placed in the housing 34 of a rear side of an apparatus body 32. Thus, the collection patterns comprising a size covering these air holes 36 are formed at an inner surface of the housing 34 in this embodiment.

An advantage similar to those of the first and second embodiments may be obtained also in this embodiment. That is, the desktop PC 30 may trap the liquid entering the housing through the air holes 36, and may easily specify the intrusion path and component of the liquid.

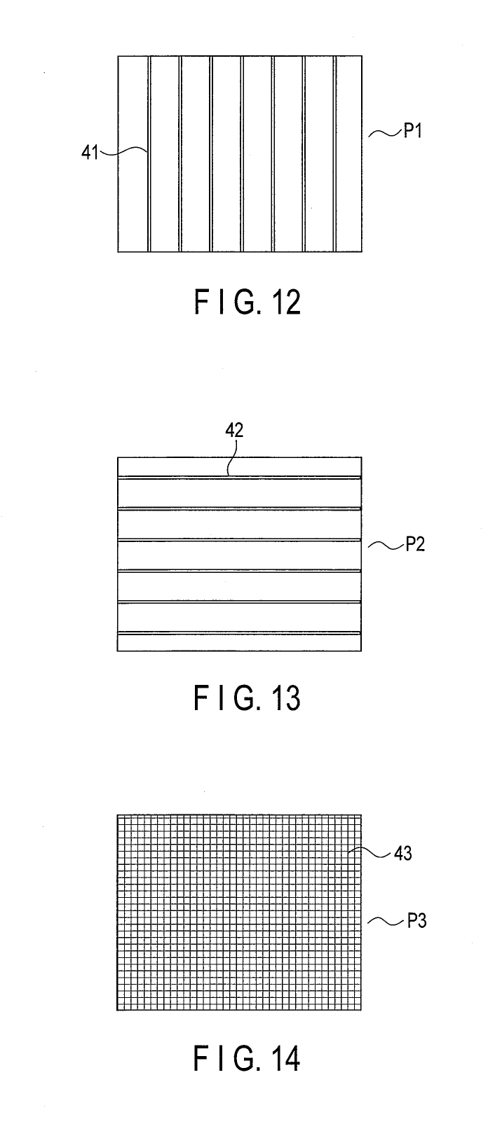

Some examples of the collection patterns P of FIGS. 7 and 10 are explained hereinafter with respect to FIGS. 12 to 17. The collection patterns P are basically intended to use the capillary phenomenon and to absorb and collect the liquid in the minute channels. The collection patterns P may comprise any structure, and the structure is arbitrarily selectable.

Collection pattern P1 of FIG. 12 comprise a structure in which minute linear grooves 41 comprising a width of approximately 100 μm and a depth of approximately 50 μm are placed in the same direction at regular intervals. Collection pattern P2 of FIG. 13 comprise a plurality of grooves 42 extended in a direction perpendicular to the grooves 41 of the above-described collection pattern P1 at regular intervals. Also, collection pattern P3 of FIG. 14 comprise a structure in which the collection pattern P1 of FIG. 12 and the collection pattern P2 of FIG. 13 are combined, and comprise a plurality of lattice-shaped grooves 43.

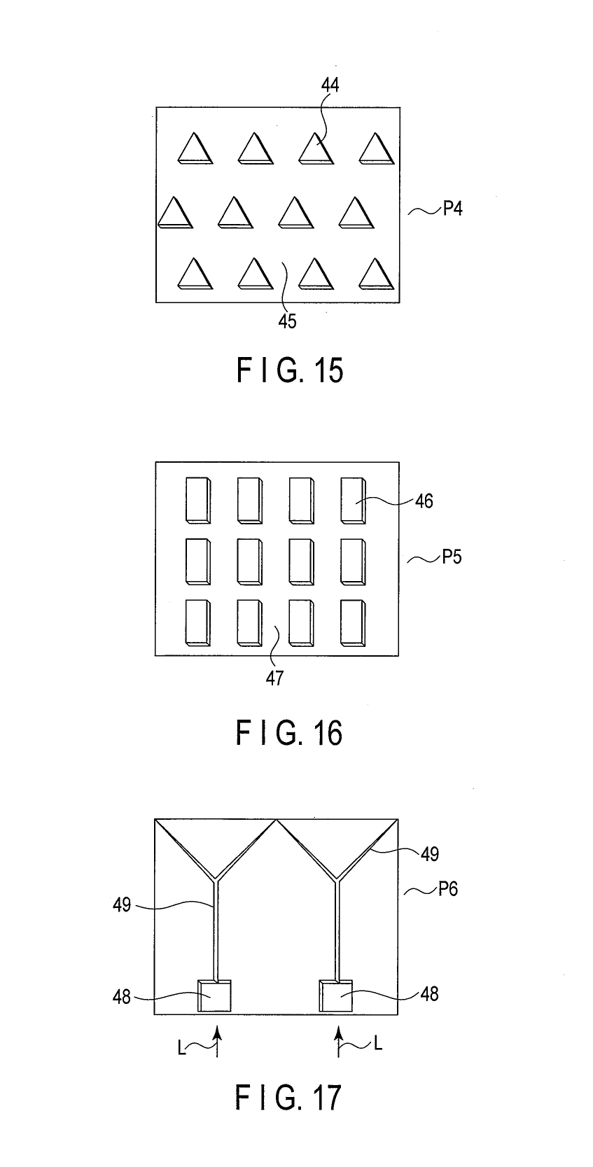

Collection pattern P4 of FIG. 15 comprises a plurality of projections 44 of regular triangular prismatic shape placed in vertical and horizontal directions, and minute channels 45 are formed between the plurality of projections 44. The channels 45 also comprise a function of absorbing the liquid by the capillary phenomenon. Also, collection pattern P5 of FIG. 16 comprise a plurality of projections 46 of quadrangular prismatic shape placed in vertical and horizontal directions, and minute channels 47 are formed between the plurality of projections 46 in the same manner as the collection pattern P4.

With respect to collection pattern P6 of FIG. 17, the liquid entering the housing from a direction L indicated by an arrow in the figure is temporarily stored in a rectangular recess 48, and the stored liquid in the recess 48 is absorbed by Y-shaped minute channels 49 branched in two directions in the middle of going upward in the figure. As shown above, the collection patterns P may comprise any form, and the channels for leading the liquid can be formed in a desired direction.

According to the electronic apparatus of one of the above-described embodiments, since the housing comprises the collection patterns P, the liquid may be collected near the intrusion path of the liquid, and the intrusion path and component of the liquid may be easily specified.

Embodiments of the present invention have been described in above. These embodiments have been presented by way of example only, and are not intended to limit the scope of the inventions. These novelties of embodiments may be embodied in a variety of other forms, various omissions, substitutions and changes in the form of the embodiment may be made without departing from the essential of the invention. These embodiments and varieties are involved with claims and essential of the invention, also their equivalents are included into the scope and essential of the inventions which are described in the claims.

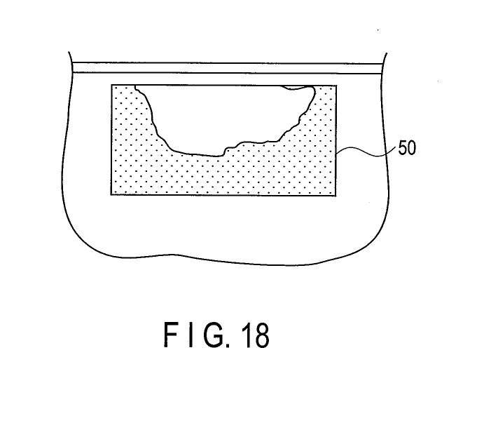

For example, the case where the collection patterns P are formed near the intrusion path of the housing of the electronic apparatus as the collecting portion is explained in the above-described embodiments. The collection patterns P are not limited to this case. Sheet-shaped porous members 50 as shown in FIG. 18 can be provided on the inside surface of the housing as the collecting portion, instead of or in addition to the collection patterns P.

In this case, the porous members 50 may be attached to the inner surface of the housing, or embedded when the housing is molded. The porous members 50 are preferably made of a material into which the liquid is easy to infiltrate. The state of infiltration is preferably confirmed by visual observation, when the liquid is infiltrated, as shown in FIG. 18.

Also, if the porous members 50 are continuously arranged along the gap (the intrusion path) of the housing, an intrusion spot of the liquid is hard to accurately detect to specify. In such a case, a plurality of porous members 50 divided into small pieces are preferably scattered along the gap.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing comprising an intrusion path through which liquid is allowed to enter the housing;
electronic components provided in the housing; and
a collecting portion configured to apply an adsorption power based on a capillary phenomenon to the liquid entering the housing from an outside of the housing through the intrusion path and to collect the liquid.

2. The electronic apparatus of claim 1, wherein
the collecting portion comprises a number of minute channels formed at a surface of the housing.

3. The electronic apparatus of claim 2, wherein
the channels comprise a pattern configured to cause the liquid entering the housing through the intrusion path to avoid the electronic components.

4. The electronic apparatus of claim 2, wherein
the channel comprises a pattern configured to lead the liquid entering the housing through the intrusion path to the electronic components.

5. The electronic apparatus of claim 1, wherein
the collecting portion comprises a porous member.

6. The electronic apparatus of claim 5, wherein
the porous member is divided into a plurality of porous members which are scattered along the intrusion path.

7. The electronic apparatus of claim 1, further comprising
a board on which the electronic components are mounted, wherein the collecting portion is provided at a surface of the board.

8. The electronic apparatus of claim 7, wherein
the collecting portion comprises a number of minute channels formed at the surface of the board.

9. The electronic apparatus of claim 8, wherein
the channel comprises a pattern configured to cause the liquid entering the housing through the intrusion path to avoid the electronic components.

10. The electronic apparatus of claim 8, wherein
the channel comprises a pattern configured to lead the liquid entering the housing through the intrusion path to the electronic components.
